(19) United States
(12) Patent Application Publication
(10) Pub. No.: US 2009/0009156 A1
(43) Pub. Date: Jan. 8, 2009

(54) Magnetic Sensor Device With Reference Unit

(75) Inventor: Haris Duric, Helmond (NL)

Correspondence Address: PHILIPS INTELLECTUAL PROPERTY & STANDARDS, P.O. BOX 3001, BRIARCLIFF MANOR, NY, 10510, US

(73) Assignee: Konninklijke Philips Electronics N.V., Eindhoven (NL)

(21) Appl. No.: 12/162,678

(22) PCT Filed: Jan. 25, 2007
(86) PCT No.: PCT/IB07/50254

§ 371 Date: Jul. 30, 2008

(30) Foreign Application Priority Data
Feb. 3, 2006 (EP) 06101252.2

(51) Int. Cl. G01R 35/00; G01R 33/09

(52) U.S. Cl. 324/202

(57) ABSTRACT

The invention relates to a magnetic sensor device comprising excitation wires (11, 13) for generating a magnetic field (B) in a sample chamber (1) and a magnetic sensor element (12), for example a GMR element, for sensing magnetic fields generated by magnetic particles (2) in the sample chamber. The device further comprises a reference field generator consisting of a linear conductor (14) and a planar conductor (15) between which the magnetic sensor element (12) is disposed. The magnetic reference field (B_{ref}) generated by said conductors (14, 15) does not penetrate into the sample chamber (1) but reaches only the magnetic sensor element (12). Components of the sensor signal which are due to the magnetic reference field (B_{ref}) can therefore be separated and used to calculate the sensor gain. This value can for example be used for an auto-calibration of the device during a measurement.

The invention relates to a magnetic sensor device comprising at least one magnetic sensor element and a sample chamber for providing a sample. Moreover, the invention relates to the use of such a magnetic sensor device and a method for measuring magnetic fields with such a magnetic sensor device.

From the WO 2005/010543 A1 and WO 2005/010542 A2 a magnetic sensor device is known which may for example be used in a microfluidic biosensor for the detection of (e.g. biological) molecules labeled with magnetic beads. The microsensor device is provided with an array of sensor units comprising wires for the generation of a magnetic field and Giant Magneto Resistance devices (GMRs) for the detection of stray fields generated by magnetized beads. The resistance of the GMRs is then indicative of the number of the beads near the sensor unit.

A problem with magnetic biosensors of the aforementioned kind is that the sensitivity of the magneto-resistive elements and therefore the effective gain of the whole measurements is very sensitive to uncontrollable parameters like magnetic instabilities in the sensors, external magnetic fields, aging, temperature and the like.

Based on this situation it was an object of the present invention to provide means for making the measurements of magnetic sensor devices more robust against variations in sensor gain.

This objective is achieved by a magnetic sensor device according to claim 1, by a method according to claim 15, and by a use according to claim 24. Preferred embodiments are disclosed in the dependent claims.

The magnetic sensor device according to the present invention comprises the following components:
a) At least one magnetic sensor element for providing a sensor signal, e.g. a voltage, wherein said sensor signal is indicative of a magnetic field (or at least a component thereof) the magnetic sensor element is (at least partially) exposed to.
b) A sample chamber in which a sample can be provided that can generate a magnetic field, which reaches the magnetic sensor element. In the most general sense, the sample chamber is just a region more or less in the vicinity of the magnetic sensor element where some magnetically interactive entity (the sample) can be provided. As its name indicates, the sample “chamber” is typically an empty cavity or a cavity arranged to immobilize (or hybridize) target molecules from the sample substance. Moreover, the sample chamber is usually a part of a microfluidic system.
c) A reference field generator for generating a magnetic “reference field” in the magnetic sensor element, wherein said reference field has a negligible strength in the sample chamber. The latter condition is typically fulfilled if the (mean or maximal) strength of the magnetic reference field in the sample chamber is less than 0.01, preferably less than 0.001, most preferably less than 0.0001 of its (mean or maximal) strength in the magnetic sensor element. Ideally, the strength of the magnetic reference field in the sample chamber is zero or at least below the detection limit.

The design of the reference field generator described above has the advantage that any magnetic interference with a sample in the sample chamber is excluded or at least reduced to undetectable levels. Thus it can be guaranteed that an observed reaction of the magnetic sensor element can unambiguously be associated to an applied magnetic reference field of known strength. This allows an accurate supervision of the sensor characteristics and particularly a calibration of its measurements.

There are different ways to realize a reference field generator that affects the magnetic sensor element but not the sample chamber. In a preferred embodiment, the reference field generator comprises at least one first conductor which is substantially linear, wherein the term “linear” shall denote that the length of the conductor is significantly larger than its maximal diameter (measured in a direction perpendicular to the length), for example 10-times, preferably 100-times larger. Thus the first conductor can be considered as being one-dimensional on a coarse scale. Typically, the first conductor is a straight wire of rectangular or circular cross section, though other, non-straight shapes are possible, too. The reference field generator further comprises a second, flat conductor which extends close to and substantially parallel to the first conductor. The term “flat” shall denote that the length and the width of the second conductor (measured in perpendicular directions) are significantly larger than its height (measured in a direction perpendicular to the length and the width), for example 10-times, preferably 100-times larger. Thus the second conductor can be considered as being two-dimensional on a coarse scale. Typically, the second conductor is realized by a planar metal sheet. The parallelism of the first and the second conductor shall refer to their dominant dimensions, i.e. to the length of the first conductor and the length and width of the second conductor. Finally, the term “close” has to be interpreted with respect to the dimensions of first and the second conductor. Thus the distance between the first and the second conductor is typically in the order of the diameter of the first conductor or the height of the second conductor, respectively, and/or smaller than the length of the first conductor or the length/width of the second conductor, respectively. In a preferred case, the distance between the first and the second conductor is 0.1-times, preferably 0.01-times the length of the first conductor.

According to a further development of the aforementioned embodiment, the first and the second conductor are shorted at one end and connected to a reference power supply at the other end (wherein the ends of the first and the second conductor shall be defined with respect to their lengths). The reference power supply may for example be a constant current source or a constant voltage source. In the described arrangement, a current can be conducted through the first conductor in one direction and returned through the second conductor in the opposite direction. As will be explained in more detail with reference to the Figures, the magnetic (reference) field generated by such a current will be substantially confined to one side of the planar conductor.

In the aforementioned embodiments, the magnetic sensor element is preferably arranged between the first and the second conductor, because the magnetic (reference) field generated by a current through the conductors will be concentrated in this region. The sample chamber, on the contrary, will preferably be arranged behind the second, flat conductor (as seen from the first conductor or the magnetic sensor element, respectively), where the magnetic reference field is substantially zero.

The space behind the second, flat conductor is maximally shielded from the magnetic reference field generated by a current in the conductors if the second conductor covers the first conductor as much as possible. Ideally, the second conductor would therefore extend infinitely in two directions. A good approximation of this ideal case is achieved if the second conductor has more than 100-times, preferably more than 200-times the width of the first conductor. The lengths of the first and the second conductor are less critical and can be approximately of the same order of magnitude, with the length of the second, flat conductor being somewhat larger than the length of the first, linear conductor.

The electrical conductivity of the second, flat conductor should be very high. This can particularly be achieved if it is realized as a metal layer, preferably a gold layer of appropriate thickness.

According to another variant of the invention, the magnetic sensor element comprises a signal separation unit for separating in the sensor signal of the magnetic sensor element reference components that are caused by the magnetic reference field from other components that may be caused by other magnetic fields or by artifacts. Thus the reaction of the magnetic sensor element to the magnetic reference field, which has a known strength, can be isolated and surveyed.

The aforementioned signal separation unit is preferably adapted to separate the signal components based on their spectral composition. If for example the reference component and the other components appear at different frequencies in the spectrum of the sensor signal, a simple band-pass filtering may be used to separate them from each other.

In a further development of the invention, the magnetic sensor device comprises at least one magnetic field generator for generating a magnetic excitation field in the sample chamber. The magnetic field generator typically comprises a conductor wire on or in a substrate of the sensor device. The magnetic excitation fields can for example be used to move magnetically interactive particles in the sample chamber and/or to magnetize magnetic beads that are used for labeling target molecules. In the latter case, the magnetic field generated by the labeling beads will be the signal of interest that shall be measured by the magnetic sensor element. The magnetic excitation field cannot be used to calibrate the magnetic sensor element because it reaches into the sample chamber and may therefore always provoke magnetic reactions of unknown size form there. Such disturbances are however excluded when the reference field generator is used.

In the aforementioned embodiment, an excitation power supply is preferably used for providing the magnetic field generator with an excitation current of a first frequency. Reactions of a sample in the sample chamber will then follow this first frequency, which allows to identify them in the spectrum of the measured sensor signal.

In a further embodiment of the invention, the magnetic sensor device comprises a reference power supply for driving the reference field generator with a reference current of a second frequency. Reactions of the magnetic sensor element that are caused by the magnetic reference field will then follow this second frequency, which allows to identify them in the spectrum of the measured sensor signal.

If the mentioned first and second frequencies are different from each other, a spectral separation of components in the sensor signal that are caused by the magnetic reference field and by a sample in the sample chamber, respectively, is possible.

According to another variant of the invention, the magnetic sensor device comprises a gain estimation unit for calculating a “gain value” that is characteristic of the sensor gain of the magnetic sensor element and/or of the gain of processing components that are coupled to the magnetic sensor element for processing its sensor signals. The gain value may for example be the sensor gain itself or its deviation from a predetermined reference value. The gain of a sensor or a processing component is as usual defined as the derivative of its output signal (e.g. a voltage) with respect to its input, i.e. the quantity to be measured in the case of a sensor (e.g. a magnetic field strength). The sensor gain is an important characteristic of the sensor behavior, and its knowledge is necessary for an accurate quantitative evaluation of measurements. The same is true for the gain of post-processing circuits. In connection with the signal separation unit mentioned above, the gain of the sensor and/or of other processing components can particularly be derived from the determined reference component of the sensor signal, as this unambiguously goes back to the known magnetic reference field.

In a further development of the aforementioned embodiment, the magnetic sensor device comprises an adaptation unit for adjusting the measurements of the magnetic sensor element according to the gain value as it was calculated by the gain estimation unit. Thus the estimated sensor gain is used for an online calibration of sensor measurements, which makes them robust even against gain variations on a short timescale.

There are different possibilities to realize an adaptation unit of the aforementioned kind. According to a first particular realization, the adaptation unit comprises a variable gain amplifier for amplifying the sensor signal of the magnetic sensor element. Said amplifier can then be adjusted according to the calculated gain value in such a way that the combination of sensor gain and amplifier gain remains constant.

In a second realization, the adaptation unit comprises an adjustable sensor power supply for providing the magnetic sensor element with a variable sensor current. This approach works for example if the magnetic sensor element is a magneto-resistive element which is driven by a sensor current and produces a voltage drop as sensor signal that is directly proportional to the applied sensor current.

In a further realization, the magnetic sensor device comprises an analog-to-digital converter for transforming analog sensor signals and the calculated gain value to digital values for further processing. Said processing may for example be executed by a personal computer, which allows highest flexibility with respect to the applied algorithms.

The invention further relates to a method for measuring magnetic fields originating in a sample chamber, wherein said measurement is made with at least one magnetic sensor element. The method comprises the generation of a magnetic reference field in the magnetic sensor element (or at least in a part thereof), wherein said magnetic reference field has a negligible strength in the sample chamber.

The method comprises in general form the steps that can be executed with a magnetic sensor device of the kind described above. Therefore, reference is made to the preceding description for more information on the details, advantages and improvements of that method.

A particularly important embodiment of the method comprises the separation of reference components caused by the magnetic reference field from other components in the sensor signal of the magnetic sensor element. Said separation is preferably done spectrally, i.e. based on the frequency spectrum of the sensor signal.

In another embodiment of the method, a magnetic excitation field of a first frequency is generated in the sample chamber. Thus reactions of e.g. magnetic particles in the sample chamber are marked with said first frequency for an easy detection in the sensor signal.

The magnetic reference field is preferably generated with a second frequency. Thus reactions caused by the reference field are marked with said second frequency for an easy detection in the sensor signal.

In another important embodiment of the method, a “gain value” characteristic of the sensor gain of the magnetic sensor element and/or of processing components that are coupled to the magnetic sensor element is calculated from the sensor signals of the magnetic sensor element. In a further development of this approach, measurements of the magnetic sensor element are adjusted according to the calculated gain value. This allows to make said measurements independent of variations in the gain of the sensor or other electronic components, thus significantly increasing the accuracy of the measuring procedure.

The aforementioned adjustment of measurements can particularly be achieved by varying the amplification of sensor signals, by varying the power supply to the magnetic sensor element, and/or by digital data processing.

As was already mentioned, the magnetic sensor element is optionally realized by a magneto-resistive element. This may for example be a Giant Magnetic Resistance (GMR) element, a TMR (Tunnel Magneto Resistance) element, or an AMR (Anisotropic Magneto Resistance) element.

The invention further relates to the use of the magnetic sensor device described above for molecular diagnostics, biological sample analysis, or chemical sample analysis. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

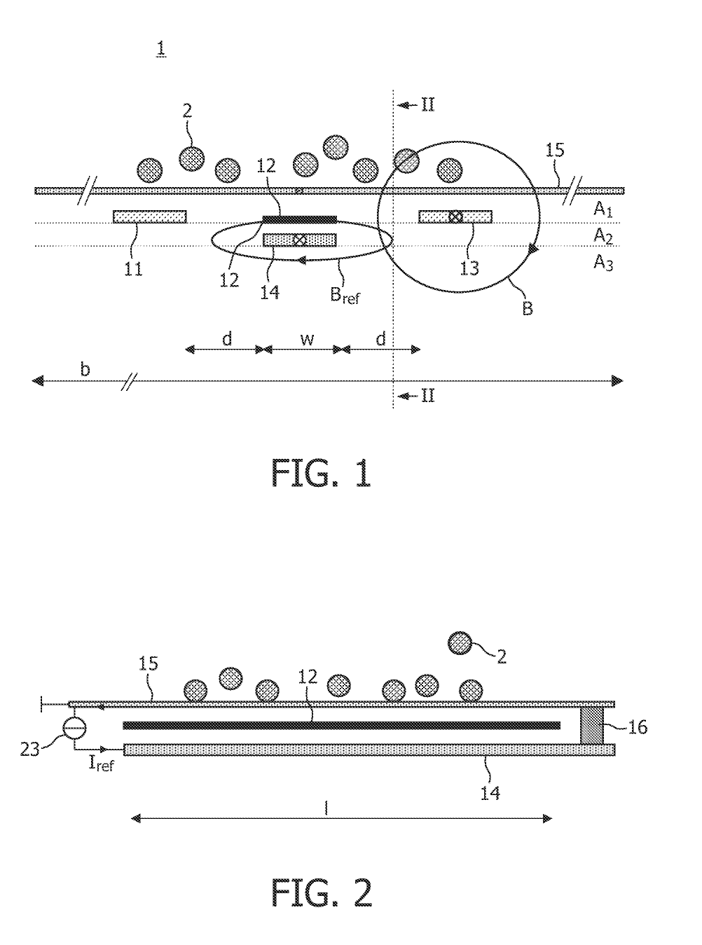

FIG. 1 shows a schematic cross section through a magnetic sensor device with a reference field generator according to the present invention;

FIG. 2 shows a schematic cross section through the magnetic sensor device of FIG. 1 in a perpendicular direction;

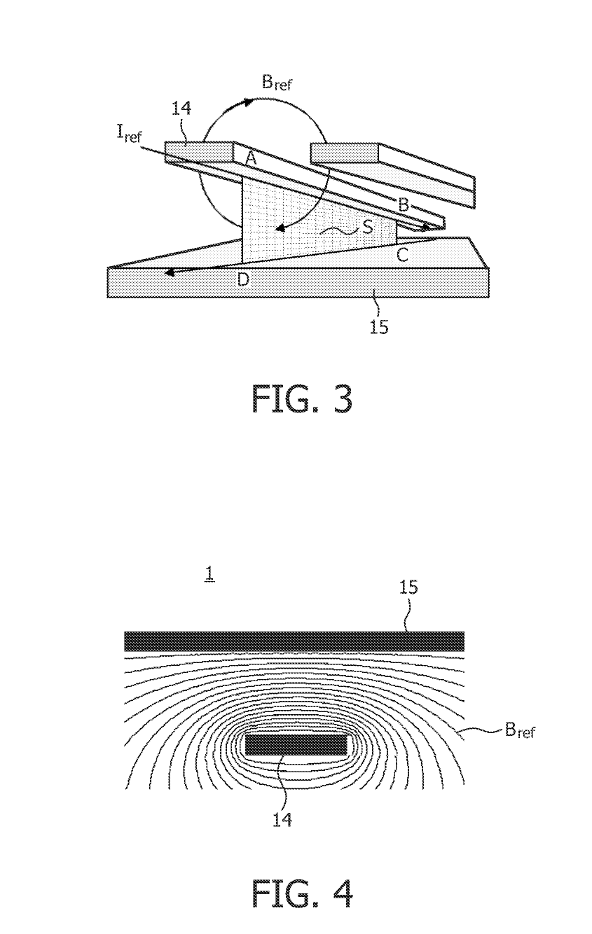

FIG. 3 illustrates in a perspective view the generation of a magnetic reference field between a linear first conductor and a planar second conductor;

FIG. 4 shows the calculated magnetic field equipotential lines of the arrangement of FIG. 3;

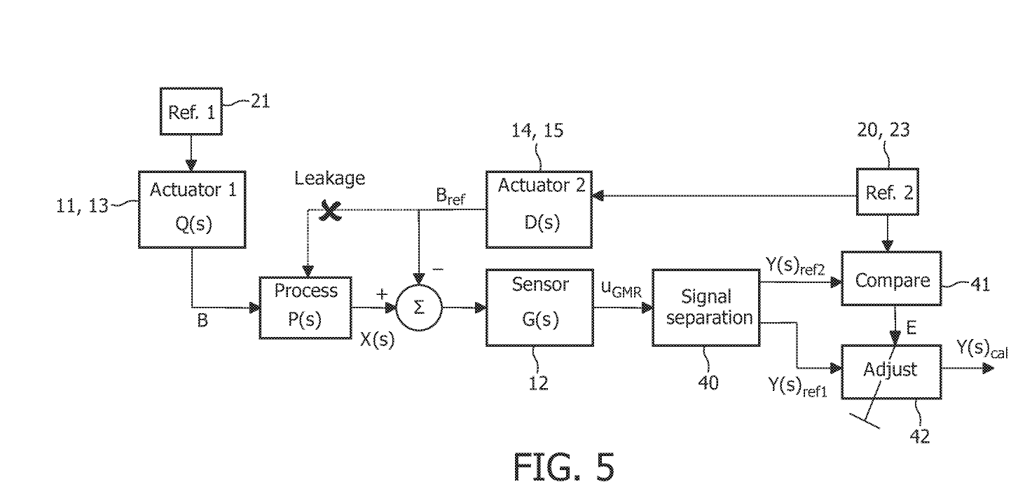

FIG. 5 is a block diagram of the magnetic sensor system with an auto-calibration according to the present invention;

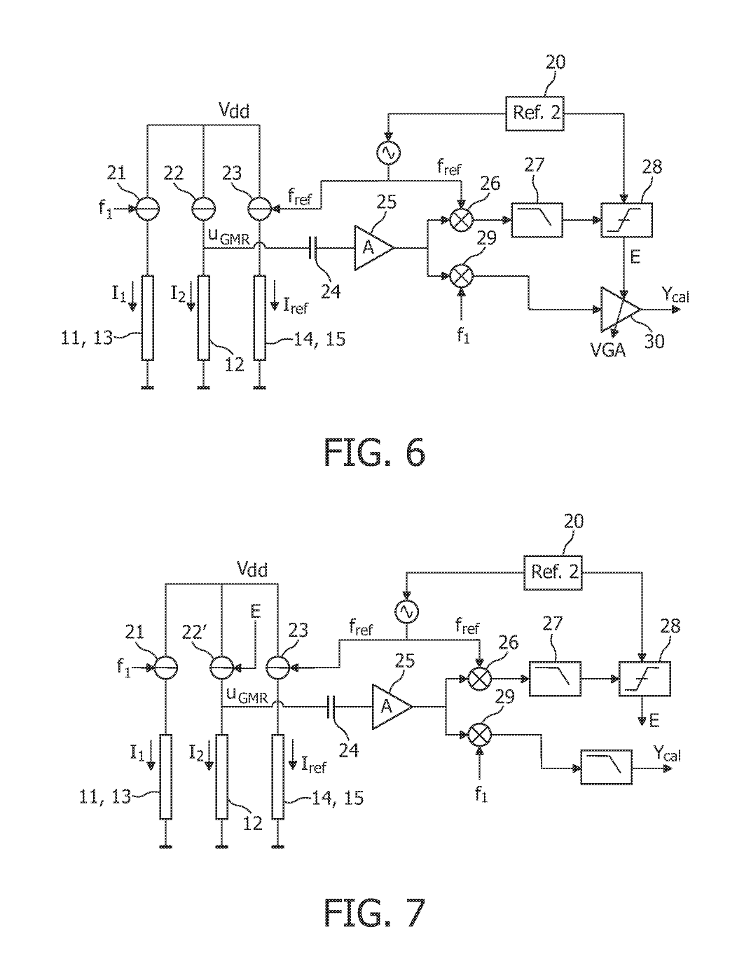

FIG. 6 shows a particular realization of the system of FIG. 5 with a variable gain amplifier;

FIG. 7 shows a particular realization of the system of FIG. 5 with an adjustment of the sensor current;

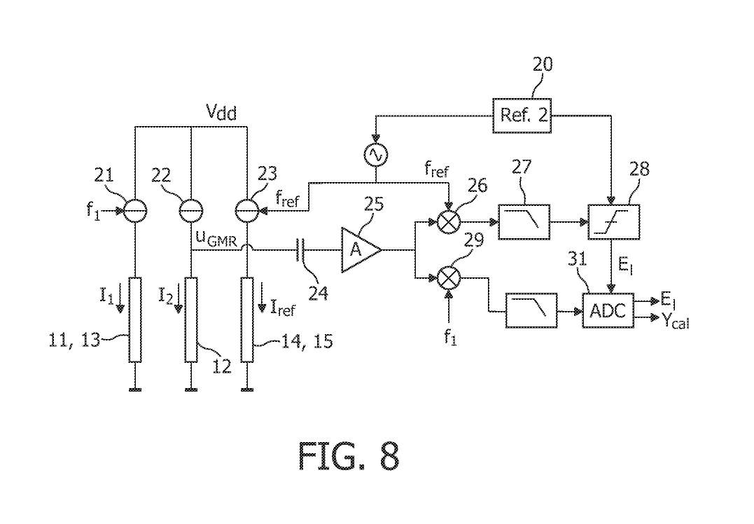

FIG. 8 shows a particular realization of the system of FIG. 5 with a conversion of analog signals for digital processing.

Like reference numbers in the Figures refer to identical or similar components.

FIG. 1 illustrates a microelectronic magnetic sensor device according to the present invention in the particular application as a biosensor for the detection of magnetically interactive particles, e.g. superparamagnetic beads 2, in a sample chamber 1. Magneto-resistive biochips or biosensors have promising properties for bio-molecular diagnostics, in terms of sensitivity, specificity, integration, ease of use, and costs. Examples of such biochips are described in the WO 2003/054566, WO 2003/054523, WO 2005/010542 A2, WO 2005/010543 A1, and WO 2005/038911 A1, which are incorporated into the present application by reference. Nevertheless, the sensor device can be any suitable sensor based on the detection of the magnetic properties of particles to be measured on or near to the sensor surface. Therefore, the magnetic sensor device is designable as a coil, magneto-resistive sensor, magneto-restrictive sensor, Hall sensor, planar Hall sensor, flux gate sensor, SQUID (Semiconductor Superconducting Quantum Interference Device), magnetic resonance sensor, or as another sensor device actuated by a magnetic field.

The magnetic sensor device shown in FIG. 1 comprises at least one magnetic field generator which is realized here by two rectangular conductor wires 11 and 13. The wires 11, 13 are driven by a current source 21 (cf. FIGS. 6-8) with an alternating excitation current I₁=I₁₀·sin(2πf₁t) of frequency f₁ for generating a magnetic excitation field B that magnetizes the magnetic beads 2 in the sample chamber 1. The beads 2 may for instance be used as labels for (bio-)molecules of interest (for more details see cited literature). Magnetic stray fields generated by the beads 2 (not shown) then affect the electrical resistance of a Giant Magneto Resistance (GMR) sensor element 12 disposed in the middle between the conductor wires 11, 13. Instead of a GMR, other magneto-resistive devices such as AMR or TMR could be used as well. A typical width w of the GMR sensor 12 is w=3 Mm, and a typical distance to the excitation wires 11, 13 may be d=3 Mm.

For measuring the aforementioned magnetic fields, an alternating or direct current I₂=I₂₀·sin(2πf₂t) of frequency f₂ is conducted through the GMR sensor element 12 by a further current source 22 (cf. FIGS. 6-8). The voltage drop U_{GMR} across the GMR sensor 12 is then a suitable sensor signal indicative of the resistance of the GMR sensor 12 and thus of the magnetic fields it is subjected to.

In a magnetic sensor device with the components described above, the magnetic sensor elements (such as AMR or GMR) often have a size that encloses more than one magnetic domain and are therefore prone to Barkhausen noise. The Barkhausen effect is a series of sudden changes in the size and orientation of ferromagnetic domains, or microscopic clusters of aligned atomic magnets. The sudden, discontinuous jumps can shift the sensitivity (or the gain) of the sensor to another point of operation. The sensitivity of magnetic sensors therefore shows large short and long-term instabilities. Especially the short-term instabilities imply that a (static) calibration point, which has been established just before or during the assay, can become useless if the sensitivity of the sensor suddenly changes during the assay. It is therefore an object of the present invention to provide convenient means and methods for a continuous auto-calibration of magnetic biosensors during a biological assay.

According to a solution proposed here, a well-defined and stable reference magnetic field is provided, which is felt only by the magnetic sensor element 12 and not by the magnetic particles 2. Such a reference field allows a dynamic auto-calibration of a magnetic sensor element and thus a continuous compensation of any cause of drift (Barkhausen noise, temperature, mechanical stress, etc.).

FIG. 1 shows additionally to the already described components a preferred realization of the aforementioned concepts. A central element of this embodiment is a “reference field generator” which comprises here a first reference conductor wire 14 extending linearly parallel to and below the GMR sensor 12, and a second, flat reference conductor 15 extending as a gold layer 15 between the sample chamber 1 on the one hand side and the excitation wires 11, 13, the GMR sensor 12, and the first conductor wire 14 on the other hand side. The first and second reference conductors thus form a sandwich structure with the GMR sensor 12 in its middle.

FIG. 2 shows in a section through the line II-II of FIG. 1 that the first reference conductor 14 and the second reference conductor 15 are shorted by a via 16 (or another connection of low impedance) at their far ends. At their front ends, the second reference conductor 15 is connected to ground and the first reference conductor 14 to a current source 20 (or alternatively a constant voltage source in series with a resistance). Thus a reference current I_{ref} can be conducted through the first, linear conductor 14 and returned through the second, flat conductor 15.

FIG. 3 shows in a schematic sketch the magnetic effect of the described arrangement of a linear first conductor and a parallel planar second conductor. In FIG. 3, one (or a plurality of) rectangular conductor(s) 14 is suspended near a ground plane 15, and a current I_{ref} is passed through the conductor(s) 14 and returned through the ground plane 15. It is known from the theory of electromagnetism that the magnetic fields are conservative. The magnetic flux Φ generated by the current I_{ref} is therefore completely confined to the area S(ABCD) between the forward and the return path of the current.

To illustrate this further, FIG. 4 shows the magnetic field equipotential lines for the arrangement of FIG. 3. It is important to notice that all magnetic field lines of the magnetic field B_{ref} are confined to only one side of the ground plane 15.

Returning now to FIGS. 1 and 2, the consequence of the above considerations is that the magnetic reference field B_{ref} generated by the first and second reference conductors 14 and 15 is spatially separated from any sample 2 in the sample chamber 1. The reference field B_{ref} is therefore only coupled to the GMR sensor 12. In contrast to this, the magnetic excitation field B of the excitation wires 11, 13 is allowed to penetrate into the sample chamber 1 above the second conductor 15 and magnetize the magnetic particles 2 therein.

FIG. 1 further indicates possible realizations of the sensor device with up to three layers A₁, A₂, A₃. In a first embodiment, the linear reference conductor 14 is realized in one of the top metal-layers of the CMOS signal-conditioning chip (layers A₂+A₃) on top of which the thin-film back-end (layer A₁) with the GMR stack 12 and other connections is deposited. The top-gold of the thin-film process is used as a ground plane or second conductor 15 and is preferably as large as possible. It may for instance cover the whole active sensor area of typically 700×700 Mm. The top-gold can be connected to a CMOS IC ground by a seal-ring in order to obtain a good ground plane.

In another embodiment, the reference conductor 14 may be located on a semiconductor substrate A₃ (e.g. Si) and for example be realized by Au embedded in a layer A₂ of Si₃N₄, on which the GMR and thin-film back-end is realized in the layer A₁.

The dimension of the reference conductors 14 and 15 may be optimized for the best magnetic field profile inside the GMR strip 12. It must however be noted that the magnetic reference field in the sample chamber 1 is exactly zero only in the case of an ideal ground plane. This ideal situation is firstly well approximated by choosing the width b of the planar top-gold conductor 15 much larger that the width w of the linear reference conductor 14. Secondly, the magnetic field penetration to the sample chamber 1 can be reduced by making the top-gold layer 15 better conductive and thicker. Thirdly, and most important: only very low magnetic fields are needed for the reference field B_{ref}, which will be flux-concentrated through the GMR stack, exactly where they are needed. The counterpart magnetic fields in the sample chamber side are easily attenuated with at least 60 dB (a factor 1000 or more), which will not affect the magnetization of the nano-particles 2 at all.

FIG. 5 shows a block diagram of a measurement with a magnetic sensor device of the kind described above. Driven by an excitation power supply 21, the excitation wires 11, 13 generate the magnetic excitation field B as an input to the process P, i.e. to the nano-particle kinetics (sedimentation, actuation, binding, etc.). At its output X, the process P generates the external magnetic field in the magnetic sensor element 12, which is the stray field generated by magnetized particles.

Driven by a reference power supply 20, 23, the reference field generator with the first and the second conductors 14, 15 generates the magnetic reference field B_{ref}.

The output of the process P and the magnetic reference field B_{ref} are superposed to yield the effective input to the magnetic sensor element 12, which generates as output the sensor signal (voltage) U_{GMR} according to its present sensor gain.

In magnetic sensor devices known from the state of the art, each magnetic field generator has some leakage to the process P, which is indicated by dashed lines in FIG. 5. Said leakage is due to the fact that the generated magnetic fields also penetrate into the sample chamber, where they may provoke (unknown) reactions of the sample. If there is leakage, it is not possible to distinguish whether a change in the sensor signal is caused by the sensor drift or by e.g. the accumulation of magnetic nano-particles on top of the sensor. In contrast to this, no leakage is present in the magnetic sensor device of the present invention (or it is at least reduced to a negligible level) due to the spatial separation of the magnetic reference field B_{ref} from the sample chamber. The reaction of the magnetic sensor element 12 to the magnetic reference field B_{ref} is therefore free from unknown disturbances, which can be exploited to determine the sensor characteristics.

Based on the above considerations, a signal separation unit 40 separates the “reference components”, which are only due to the magnetic reference field B_{ref}, from other “residual components” in the sensor signal U_{GMR}. A comparator 41 can then determine the actual sensor gain of the magnetic sensor element 12 from a comparison between said reference components of the sensor signal on the one hand side and the output of the reference power supply 20, 23 on the other hand side. Alternatively or additionally, the comparator 41 can determine the gain of other electronic components that are involved in the processing of the sensor signals, too. An adjustable processor 42 for the residual components of the sensor signal can therefore be adjusted by the comparator 41 according to an error signal E reflecting drifts in the determined gain value in order to generate an output Y_{cal} that is auto-calibrated with respect to the variable sensor gain and/or other gain variations.

During an actual measurement, the excitation power supply 21 provides an excitation current to the excitation wires 11, 13. In the first instance there are no magnetic nano-particles near the sensor 12. The resulting overall system output Y_{cal}(s) is therefore stored into the system memory as a zero level. Subsequently, the biological assay is performed, and the difference of the then obtained system output Y_{cal}(S) to the stored zero level contains the biological information. During the measurement, any drift due to e.g. magnetic domain fluctuations, temperature or mechanical stress is compensated. As a result of the continuous and simultaneous nature of the auto-calibration method, not only the last value, but all intermediate signal values may be utilized to monitor the assay kinetics and to extract information.

FIG. 6 shows a first concrete realization of the system of FIG. 5. The excitation wires 11, 13 are driven with an alternating current I₁ of excitation frequency f₁ by the excitation power supply 21. The GMR sensor 12 is driven with a DC current I₂ by the current source 22, and the reference field conductors 14, 15 are driven with a reference current I_{ref} by a reference power supply 23. The frequency f_{ref} of the reference current I_{ref} is set by a frequency selector 20.

The voltage U_{GMR} across the GMR sensor 12 represents the sensor signal, which is sampled via a capacitor 24 and an amplifier 25. The amplified sensor signal is then, in a lower branch of the processing circuitry, modulated with the excitation frequency f₁ to extract the desired signal which appears at the excitation frequency f₁. The demodulated signal is then sent through a variable gain amplifier 30 to yield the final sensor output Y_{cal}.

In the upper branch of the processing circuitry, the amplified sensor signal is sent to a second demodulator 26 which is driven with the reference frequency f_{ref} in order to extract the reference components from the signal that are due to the magnetic reference field B_{ref}. The extracted reference components are then sent through a low pass filter 27 to a gain estimation unit 28 which determines the present sensor gain and/or the gain of other processing components, particularly of the amplifier 25, from the relation between the extracted reference components of the sensor signal and the output of the frequency selector 20 (which drives the reference field generator). The deviation E of the calculated gain value from a predetermined base level is then used to adjust the gain of the variable gain amplifier 30 accordingly.

It should be noted that the described method can not only deal with variations in the sensor behavior, but also with inaccuracies introduced by the signal-processing electronics. Thus the gain of the amplifier 25 and of other electronic circuits is not exactly known and depends on the process variations, component tolerances, etc., which is a problem for a quantitative measurement. Furthermore, the associated (electronic) gain is also subject to temperature drift. The presented calibration method removes effectively these additional inaccuracies by first determining the associated gain value and then compensating the measurements accordingly.

In the embodiment of FIG. 6, the GMR sensor 12 is biased by a DC current source 22, the excitation wires 11, 13 are modulated by a frequency of e.g. f₁=1 MHz, and the reference conductors 14, 15 are modulated by a reference frequency of e.g. f_{ref}=10 MHz. The external magnetic signal and the reference signal are separated first in space (magnetic particles are not affected by f_{ref}) and then in the frequency domain.

Because the sensor device is calibrated continuously from the moment where there are no magnetic particles near the GMR sensor 12 until the end of the assay, there is no need for a modulation of the GMR sensor bias current I₂ (the capacitive and inductive coupling are removed by calibration). This is very advantageous since it is much more easy to construct a DC low-noise current source than an AC low-noise current source. If preferred, the GMR sensor current may however be modulated by a non-zero frequency of e.g. f₂=1 kHz, and the signal can be extracted in the demodulator 29 at f₁±f₂.

FIG. 7 shows an alternative realization of the system of FIG. 5, wherein the deviation E of the sensor gain determined by the gain estimation unit 28 is used as input to the adjustable sensor power supply 22′. Thus the magnitude of the sensor current I₂ is adjusted to compensate for sensor drifts.

In the embodiment of FIG. 8, the deviation E of the sensor gain determined by the gain estimation unit 28 and the demodulated sensor signal leaving the demodulator 29 are converted to the digital domain by an analog-to-digital converter 31. Thus further processing and particularly the calibration of the data can be achieved by versatile microcomputers.

By providing means for a simultaneous spatial and frequency separation of the reference

signal and the magnetic signal originating from the assay, the sensor devices according to the present invention can be auto-calibrated, thus compensating for any cause of drift

(Barkhausen noise, temperature, mechanical stress, etc.). This improves the accuracy of the magnetic sensor device significantly.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device, comprising
a) at least one magnetic sensor element (12) for providing a sensor signal (U_{GMR}) indicative of a magnetic field to which the sensor element is exposed;
b) a sample chamber (1) in which a sample that generates a magnetic field reaching the magnetic sensor element (12) can be provided;
c) a reference field generator (14, 15) for generating a magnetic reference field (B_{ref}) in the magnetic sensor element (12) which has negligible strength in the sample chamber (1).

2. The magnetic sensor device according to claim 1,
characterized in that the reference field generator comprises at least one first, linear conductor (14) and a second, flat conductor (15) extending close to and substantially parallel to the first conductor.

3. The magnetic sensor device according to claim 2,
characterized in that the first and the second conductor (14, 15) are shorted at one end and connected to a reference power supply (20, 23) at the other end.

4. The magnetic sensor device according to claim 2,
characterized in that the magnetic sensor element (12) is arranged between the first conductor (14) and the second conductor (15).

5. The magnetic sensor device according to claim 2,
characterized in that the width (b) of the second conductor (15) is more than 100 times, preferably more than 200 times the width (w) of the first conductor (14).

6. The magnetic sensor device according to claim 2,
characterized in that the second conductor (15) comprises a metal layer, preferably a gold layer.

7. The magnetic sensor device according to claim 1,
characterized in that it comprises a signal separation unit (40) for separating in the sensor signal (U_{GMR}) of the magnetic sensor element (12) reference components caused by the magnetic reference field (B_{ref}) from other components.

8. The magnetic sensor device according to claim 7,
characterized in that the signal separation unit (40) is adapted to separate the signal components based on their spectral composition.

9. The magnetic sensor device according to claim 1,
characterized in that it comprises at least one magnetic field generator (11, 13) for generating a magnetic excitation field (B) in the sample chamber (1).

10. The magnetic sensor device according to claim 9,
characterized in that it comprises an excitation power supply (21) for providing the magnetic field generator (11, 13) with an excitation current of a first frequency.

11. The magnetic sensor device according to claim 1,
characterized in that it comprises a reference power supply (20, 23) for driving the reference field generator (14, 15) with a reference current of a second frequency.

12. The magnetic sensor device according to claim 1,
characterized in that it comprises a gain estimation unit (28) for calculating a gain value characteristic of the sensor gain of the magnetic sensor element (12) and/or of processing components (25, 26, 27) that are coupled to the magnetic sensor element (12).

13. The magnetic sensor device according to claim 12,
characterized in that it comprises an adaptation unit (22′, 30, 42) for adjusting the measurements of the magnetic sensor element (12) according to the calculated gain value.

14. The magnetic sensor device according to claim 13,
characterized in that the adaptation unit comprises a variable gain amplifier (30), an adjustable sensor power supply (22′) for providing the magnetic sensor element (12) with a variable sensor current, and/or an analog-to-digital converter (31) for transforming analog sensor signals (U_{GMR}) and/or the calculated gain value to digital values for further processing.

15. A method for measuring a magnetic field originating in a sample chamber (1) with at least one magnetic sensor element (12), wherein a magnetic reference field (B_{ref}) is generated in the magnetic sensor element (12) which has negligible strength in the sample chamber.

16. The method according to claim 15,
characterized in that reference components caused by the magnetic reference field (B_{ref}) are—preferably spectrally—separated from other components in the sensor signal (U_{GMR}) of the magnetic sensor element (12).

17. The method according to claim 15,
characterized in that a magnetic excitation field (B) of a first frequency is generated in the sample chamber (1).

18. The method according to claim 15,
characterized in that the magnetic reference field (B_{ref}) is generated with a second frequency.

19. The method according to claim 15,
characterized in that a gain value characteristic of the sensor gain of the magnetic sensor element (12) and/or of processing components (25, 26, 27) that are coupled to the magnetic sensor element (12) is calculated from the sensor signal (U_{GMR}) of the magnetic sensor element (12).

20. The method according to claim 19,
characterized in that the measurements of the magnetic sensor element (12) are adjusted according to its calculated gain value.

21. The method according to claim 20,
characterized in that the measurements are adjusted by varying the amplification of sensor signals (U_{GMR}), by varying the power supplied to the magnetic sensor element (12), and/or by digital data processing.

22. The magnetic sensor device according to claim 1,
characterized in that the strength of the magnetic reference field (B_{ref}) in the sample chamber (1) is less than 0.01, preferably less than 0.001, most preferably less than 0.0001 of its strength in the magnetic sensor element (12).

23. The magnetic sensor device according to claim 1,
characterized in that the magnetic sensor element (12) comprises a magneto-resistive element like a GMR (12), a TMR, or an AMR element.

24. Use of the magnetic sensor device according to claim 1 for molecular diagnostics, biological sample analysis, or chemical sample analysis.
